(19) United States
(12) Patent Application Publication
(10) Pub. No.: US 2026/0045944 A1
(43) Pub. Date: Feb. 12, 2026

(54) ELECTRONIC CIRCUITRY, METHOD OF DRIVING MULTI-GATE ELEMENT, AND ELECTRONIC SYSTEM

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Atsushi YAMAOKA, Yokohama (JP); Thomas Martin HONE, Hayama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/283,590

(22) Filed: Jul. 29, 2025

(30) Foreign Application Priority Data
Aug. 8, 2024 (JP) 2024-133372

(51) Int. Cl. H03K 17/16

(52) U.S. Cl. CPC H03K 17/168

(57) ABSTRACT

According to one embodiment, an electronic circuitry includes a control circuit configured to control a rise timing of a first pulse signal applied to a first control gate electrode of a multi-gate element; and a comparator circuit configured to acquire a comparison result: between a voltage associated with an inter-electrode voltage between a first electrode and a second electrode of the multi-gate element; and a first voltage or a second voltage smaller than the first voltage. The control circuit is configured to, based on the comparison result, acquire transition time corresponding to a duration from when the voltage associated with the inter-electrode voltage falls below the first voltage to when the voltage associated with the inter-electrode voltage falls below the second voltage during turn-on of the multi-gate element, and adjust the rise timing of the first pulse signal so as to reduce the transition time.

### CROSS REFERENCE TO RELATED APPLICATIONS

This application is based upon and claims the benefit of priority from the prior Japanese Patent Application No. 2024-133372, filed on Aug. 8, 2024, the entire contents of which are incorporated herein by reference.

### FIELD

Embodiment described herein relates to an electronic circuitry, a method of driving a multi-gate element, and an electronic system.

### BACKGROUND

A multi-gate IGBT (Insulated Gate Bipolar Transistor) that has a plurality of gate electrodes and is capable of reducing turn-on loss and turn-off loss by contriving a pattern of pulse signals applied to each gate electrode is known. The multi-gate IGBT includes a control gate electrode for increasing and decreasing a stored carrier density in addition to a regular electrode for conduction control. By controlling the pattern of pulse signals applied to the control gate electrode so as to instantaneously increase a current by increasing the stored carrier density at the time of turn-on and reducing the stored carrier density stepwise at the time of turn-off, switching loss of an element can be reduced.

### BRIEF DESCRIPTION OF THE DRAWINGS

FIG. 1 is a diagram illustrating a configuration of a drive system of a multi-gate element according to Embodiment 1;

FIG. 2 is a diagram illustrating an example of a pattern of each pulse signal of a TG-IGBT;

FIG. 3 is a diagram illustrating a detailed configuration of a comparator circuit according to Embodiment 1;

FIG. 4 is a diagram illustrating temporal change at the time of turn-on of a voltage “Vn”;

FIG. 5 is a diagram illustrating a relation between turn-on loss and transition time;

FIG. 6 is a diagram illustrating a relation between the turn-on loss and the transition time;

FIG. 7 is a diagram describing details of feedback control according to Embodiment 1;

FIG. 8 is a diagram describing details of the feedback control according to Embodiment 1;

FIG. 9 is a diagram illustrating a configuration of a drive system of the multi-gate element according to Embodiment 2;

FIG. 10 is a diagram illustrating a configuration of a drive system of the multi-gate element according to Embodiment 3;

FIG. 11 is a diagram illustrating a detailed configuration of a comparator circuit according to Embodiment 3; and

FIG. 12 is a diagram illustrating a relation between the turn-on loss and second elapsed time.

### DETAILED DESCRIPTION

According to one embodiment, an electronic circuitry includes a control circuit configured to control a rise timing of a first pulse signal applied to a first control gate electrode of a multi-gate element; and a comparator circuit configured to acquire a comparison result: between a voltage associated with an inter-electrode voltage between a first electrode and a second electrode of the multi-gate element; and a first voltage or a second voltage smaller than the first voltage. The control circuit is configured to, based on the comparison result, acquire transition time corresponding to a duration from when the voltage associated with the inter-electrode voltage falls below the first voltage to when the voltage associated with the inter-electrode voltage falls below the second voltage during turn-on of the multi-gate element, and adjust the rise timing of the first pulse signal so as to reduce the transition time.

According to one embodiment, a method of driving a multi-gate element, includes: acquiring a comparison result between a voltage associated with an inter-electrode voltage between a first electrode and a second electrode of the multi-gate element and a first voltage or a second voltage smaller than the first voltage; acquiring transition time corresponding to a duration from when the voltage associated with the inter-electrode voltage falls below the first voltage to when the voltage associated with the inter-electrode voltage falls below the second voltage during turn-on of the multi-gate element; and
adjusting a rise timing of a first pulse signal applied to a first control gate electrode of the multi-gate element so as to reduce the transition time.

According to one embodiment, an electronic system includes: a multi-gate element; a control circuit configured to control a rise timing of a first pulse signal applied to a first control gate electrode of the multi-gate element; and a comparator circuit configured to acquire a comparison result between a voltage associated with an inter-electrode voltage between a first electrode and a second electrode of the multi-gate element and a first voltage or a second voltage smaller than the first voltage, wherein the control circuit is configured to, based on the comparison result, acquire transition time corresponding to a duration from when the voltage associated with the inter-electrode voltage falls below the first voltage to when the voltage associated with the inter-electrode voltage falls below the second voltage during turn-on of the multi-gate element, and adjust the rise timing of the first pulse signal so as to reduce the transition time.

Hereinafter, the present embodiment will be described with reference to the drawings. In the drawings, identical or corresponding elements are denoted by the same reference signs and detailed description is appropriately omitted.

### Embodiment 1

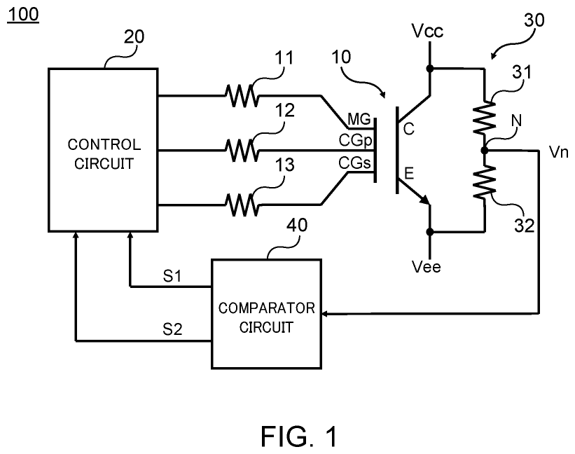

FIG. 1 is a diagram illustrating a configuration of a drive system 100 (electronic system) of a multi-gate element according to Embodiment 1. The drive system 100 includes a triple-gate IGBT 10 (TG-IGBT 10) which is an example of the multi-gate element, a control circuit 20, a voltage divider circuit 30, and a comparator circuit 40. The control circuit 20, the voltage divider circuit 30, and the comparator circuit 40 form an electronic circuitry that drives the TG-IGBT 10. The multi-gate element includes a double-gate IGBT (DG-IGBT) for example, in addition to the triple-gate IGBT.

The TG-IGBT 10 includes a main gate electrode MG, a primary control gate electrode CGp (second control gate electrode), a secondary control gate electrode CGs (first control gate electrode), a collector electrode C (first electrode), and an emitter electrode E (second electrode). The main gate electrode MG is used to control conduction between a collector and an emitter, similarly to a gate electrode of a regular single-gate IGBT. The primary control gate electrode CGp and the secondary control gate electrode CGs are used to control a stored carrier density. Specifically, the primary control gate electrode CGp is used to draw out charges in advance at the time of turn-off. The secondary control gate electrode CGs is used to supply charges at the time of turn-on.

The control circuit 20 is formed of, for example, an FPGA (Field Programmable Gate Array), a CPU (Central Processing Unit), or an ASIC (Application Specified Integrated Circuit). The control circuit 20 applies a main pulse signal to the main gate electrode MG of the TG-IGBT 10 via a gate resistor 11. The control circuit 20 applies a primary pulse signal (second pulse signal) to the primary control gate electrode CGp of the TG-IGBT 10 via a gate resistor 12. The control circuit 20 applies a secondary pulse signal (first pulse signal) to the secondary control gate electrode CGs of the TG-IGBT 10 via a gate resistor 13. The control circuit 20 controls a switching operation of the TG-IGBT 10 by controlling rise and fall of each pulse signal.

Values of the gate resistors 11 to 13 may be the same or may be different. Further, a gate resistor for the time when the pulse signal is a positive voltage and a gate resistor for the time when it is a negative voltage may be separately provided. In this case, a diode is connected in series with the gate resistor, a diode mounted in series with the gate resistor used in a current route at the time of the positive voltage is mounted such that an anode is on a side of the control circuit 20 and a cathode is on a gate electrode side, and a diode mounted in series with the gate resistor used in a current route at the time of the negative voltage is mounted such that the anode is on the gate electrode side and the cathode is on the side of the control circuit 20. In addition, since the multi-gate element generally has a large gate capacity, a current amplifier circuit may be added to output of the control circuit 20 in order to supply charges at a high speed to each gate electrode of the TG-IGBT 10.

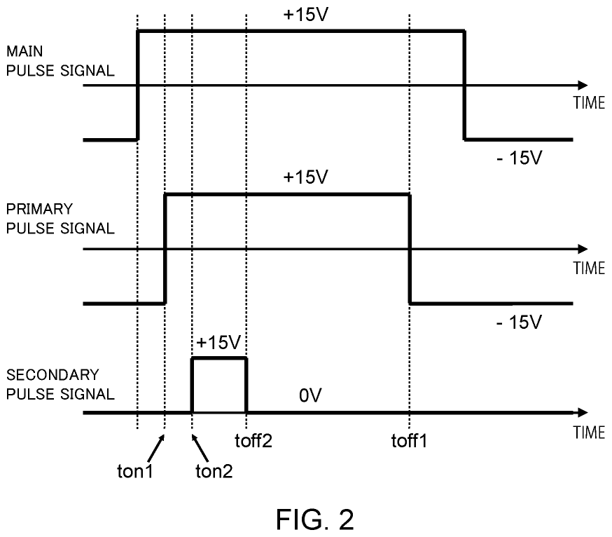

FIG. 2 is a diagram illustrating an example of a pattern of the pulse signal applied to each gate electrode of the TG-IGBT 10. By the main pulse signal applied to the main gate electrode MG, the conduction between the collector and the emitter of the TG-IGBT 10 is controlled. The main pulse signal is +15 V on a high voltage side, and is −15 V on a low voltage side. When the main pulse signal rises to +15 V, the collector and the emitter of the TG-IGBT 10 become conductive. However, a value on the high voltage side of the main pulse signal is not limited to +15 V, and only needs to exceed a threshold voltage determined by characteristics of the TG-IGBT 10. Similarly, a value on the low voltage side of the main pulse signal is not limited to −15 V either, and only needs to be below the threshold voltage.

The primary pulse signal applied to the primary control gate electrode CGp is controlled mainly for a purpose of reducing turn-off loss. The primary pulse signal is +15 V on the high voltage side, and is −15 V on the low voltage side. However, a value on the high voltage side of the primary pulse signal is not limited to +15 V, and only needs to exceed the threshold voltage determined by the characteristics of the TG-IGBT 10. Similarly, a value on the low voltage side of the primary pulse signal is not limited to −15 V either, and only needs to be below the threshold voltage.

A rise timing “ton1” and a fall timing “toff1” of the primary pulse signal are defined as relative delay time from a rise timing of the main pulse signal. For example, when “ton1” is zero or larger, the primary pulse signal rises “ton1” after the rise timing of the main pulse signal, and falls “toff1” after the rise timing of the main pulse signal. On the other hand, when “ton1” is smaller than zero, the primary pulse signal rises “ton1” before the rise timing of the main pulse signal, and falls “toff1” before the rise timing of the main pulse signal. However, “ton1” and “toff1” may be defined with another timing as a reference. The fall timing “toff1” of the primary pulse signal affects the turn-off loss. The rise timing “ton1” of the primary pulse signal affects turn-on loss.

The secondary pulse signal applied to the secondary control gate electrode CGs is controlled mainly for a purpose of reducing the turn-on loss. The secondary pulse signal is +15 V on the high voltage side, and is 0 V on the low voltage side. However, a value on the high voltage side of the secondary pulse signal is not limited to +15 V, and only needs to exceed the threshold voltage determined by the characteristics of the TG-IGBT 10. Similarly, a value on the low voltage side of the secondary pulse signal is not limited to 0 V either, and only needs to be below the threshold voltage.

A rise timing “ton2” and a fall timing “toff2” of the secondary pulse signal are defined as the relative delay time from the rise timing of the main pulse signal. For example, when “ton2” is zero or larger, the secondary pulse signal rises “ton2” after the rise timing of the main pulse signal, and falls “toff2” after the rise timing of the main pulse signal. On the other hand, when “ton2” is smaller than zero, the secondary pulse signal rises “ton2” before the rise timing of the main pulse signal, and falls “toff2” before the rise timing of the main pulse signal. However, “ton2” and “toff2” may be defined with another timing as a reference. The rise timing “ton2” of the secondary pulse signal affects the turn-on loss. The secondary pulse signal preferably becomes +15 V for a short time only at the time of the turn-on and falls immediately, in order to prevent decline of short circuit tolerance of the TG-IGBT 10.

The control circuit 20 reduces the turn-on loss of the TG-IGBT 10 by adjusting two parameters of four parameters (“ton1”, “toff1”, “ton2”, and “toff2”) illustrated in FIG. 2, specifically, the rise timing “ton1” of the primary pulse signal and the rise timing “ton2” of the secondary pulse signal. In addition, the control circuit 20 reduces the turn-off loss of the TG-IGBT 10 by adjusting the fall timing “toff1” of the primary pulse signal, and prevents the decline of the short circuit tolerance of the TG-IGBT 10 by adjusting the fall timing “toff2” of the secondary pulse signal. However, since a main object of the present embodiment is to reduce the turn-on loss of the TG-IGBT 10, description will be given assuming that “toff1” and “toff2” are fixed at values determined in advance.

Referring back to FIG. 1, the voltage divider circuit 30 is formed of a resistor 31 and a resistor 32, and divides a collector-emitter voltage “Vce” of the TG-IGBT 10 at a predetermined ratio. A voltage division ratio is set such that a maximum value of a voltage “Vn” is within an inputtable voltage level of the comparator circuit 40. As an example, when a resistance ratio is set at 9:1, the voltage “Vn” which is 1/10 of the collector-emitter voltage “Vce” appears at a node N of the voltage divider circuit 30.

At least one of the resistor 31 and the resistor 32, for example, the resistor 31 connected to a collector side of the TG-IGBT 10 may be formed of a variable resistor, a digital potentiometer for example, and may be formed of series connection of a fixed resistor and a variable resistor. Thus, the voltage division ratio can be easily adjusted. Further, a capacitor may be used instead of the resistor.

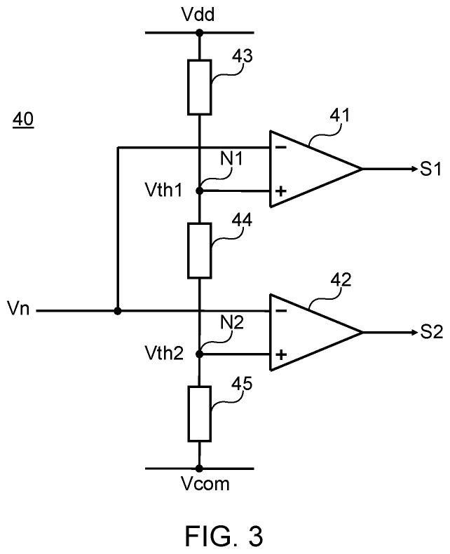

The comparator circuit 40 acquires a comparison result of the voltage “Vn” divided by the voltage divider circuit 30 and a first voltage “Vth1” or a second voltage “Vth2”. More specifically, the voltage “Vn” and the first voltage “Vth1” or the second voltage “Vth2” are compared respectively and the comparison result is output. The first voltage “Vth1” may be a first threshold voltage that is a voltage associated with turn-on start. The second voltage “Vth2” may be a second threshold voltage that is a voltage associated with turn-on completion. FIG. 3 is a diagram illustrating a detailed configuration of the comparator circuit 40. The comparator circuit 40 includes a first comparator 41, a second comparator 42, and three resistors 43 to 45 connected in series between a positive voltage V1 and a common voltage Vcom. The positive voltage V1 is, for example, +5 V used in a general electronic device.

By appropriately setting values of the resistors 43 to 45, a voltage at a node N1 is set at the first voltage “Vth1”, and a voltage at a node N2 is set at the second voltage “Vth2”. The voltage “Vn” is input to negative input of the first comparator 41, and the first voltage “Vth1” is input to positive input. The voltage “Vn” is input to negative input of the second comparator 42, and the second voltage “Vth2” is input to positive input.

The first comparator 41 outputs “Low” while the voltage “Vn” exceeds the first voltage “Vth1”, and outputs “High” when the voltage “Vn” falls below the first voltage “Vth1”. Output of the first comparator 41 is a first comparison signal S1 and is input to the control circuit 20. The second comparator 42 outputs “Low” while the voltage “Vn” exceeds the second voltage “Vth2”, and outputs “High” when the voltage “Vn” falls below the second voltage “Vth2”. Output of the second comparator 42 is a second comparison signal S2 and is input to the control circuit 20.

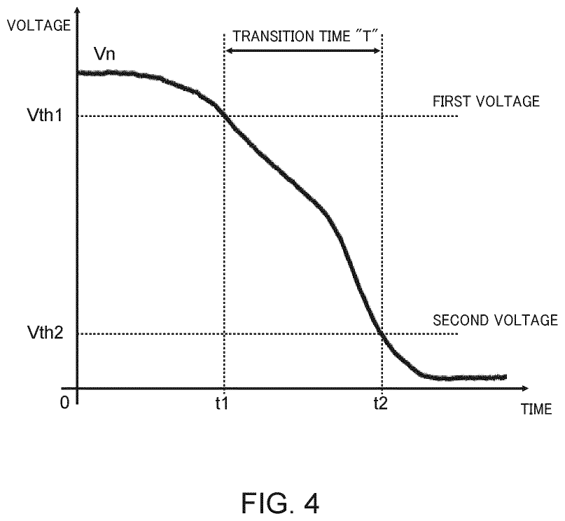

The first voltage “Vth1” and the second voltage “Vth2” are set such that transition time “T” from when the voltage “Vn” falls below “Vth1” to when it falls below “Vth2” is roughly equal to turn-on time of the TG-IGBT 10. More specifically, as illustrated in FIG. 4, the first voltage “Vth1” is set at a value slightly lower than the voltage “Vn” when the TG-IGBT 10 is not conductive. This is for accurately acquiring a timing that can be regarded as the turn-on start while avoiding influence of fluctuation of the voltage “Vn” immediately after the turn-on start. As an example, the first voltage “Vth1” is set to 0.91 times the maximum value of the voltage “Vn”.

The second voltage “Vth2” is set at a value slightly higher than the voltage “Vn” when the TG-IGBT 10 is conductive. This is for accurately acquiring a timing that can be regarded as the turn-on completion while avoiding influence of fluctuation of the voltage “Vn” immediately before the turn-on completion. As an example, the second voltage “Vth2” is set to 0.16 times the maximum value of the voltage “Vn”.

By setting the first voltage “Vth1” and the second voltage “Vth2” as described above, the transition time “T” from when the voltage “Vn” falls below the first voltage “Vth1” and the first comparison signal S1 changes from “Low” to “High” to when the voltage “Vn” falls below the second voltage “Vth2” and the second comparison signal S2 changes from “Low” to “High” becomes roughly equal to the turn-on time of the TG-IGBT 10.

The control circuit 20 measures the transition time “T” by its own built-in counter for example. More specifically, the control circuit 20 turns on the built-in counter at a timing (t1 in FIG. 4) at which the first comparison signal S1 output from the comparator circuit 40 changes from “Low” to “High”, and turns off the built-in counter at a timing (t2 in FIG. 4) at which the second comparison signal S2 output from the comparator circuit 40 changes from “Low” to “High”. Note that, when the transition time “T” is short and a sampling frequency exceeding an operation frequency of the control circuit 20 is demanded, a component capable of realizing higher time resolution, such as a TDC (Time to Digital Converter), may be used instead of the built-in counter.

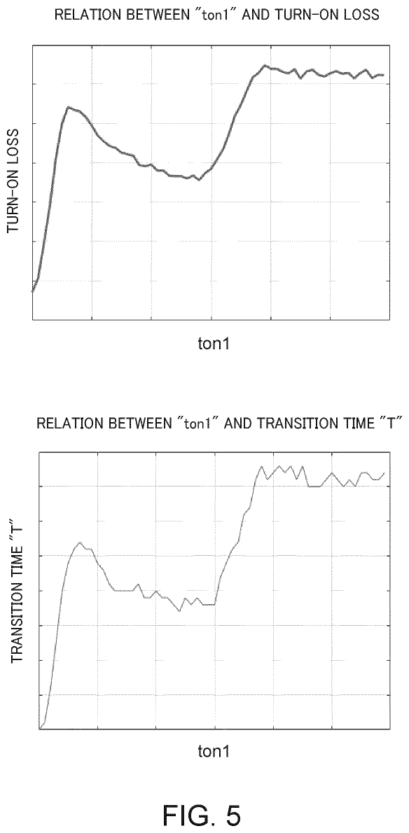

Here, a relation between the turn-on loss of the TG-IGBT 10 and the transition time “T” will be described. A graph on an upper side of FIG. 5 illustrates a relation between “ton1” when “ton1” is manually changed and the turn-on loss. A graph on a lower side of FIG. 5 illustrates a relation between “ton1” when “ton1” is manually changed and the transition time “T”. When the two graphs are compared, both are correlated. Therefore, the control circuit 20 can minimize the turn-on loss of the TG-IGBT 10 by adjusting “ton1” so as to minimize the transition time “T”. In an example in FIG. 5, the control circuit 20 needs to make “ton1” be equal to zero.

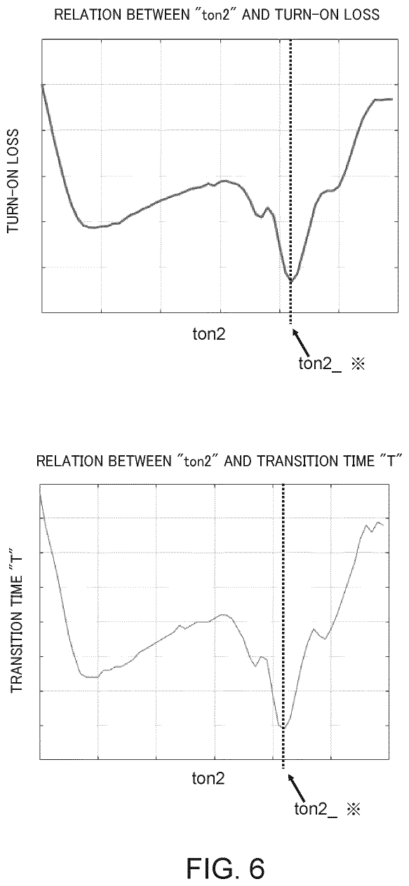

A graph on an upper side of FIG. 6 illustrates a relation between “ton2” when “ton2” is manually changed and the turn-on loss. A graph on a lower side of FIG. 6 illustrates a relation between “ton2” when “ton2” is manually changed and the transition time “T”. When the two graphs are compared, both are correlated. Therefore, the control circuit 20 can minimize the turn-on loss of the TG-IGBT 10 by adjusting “ton2” so as to minimize the transition time “T”. In an example in FIG. 6, the control circuit 20 needs to make “ton2” be equal to “ton2_*” in the figure.

As described above, by utilizing correlation between the turn-on loss of the TG-IGBT 10 and the transition time “T” and adjusting “ton1” and “ton2” so as to minimize the transition time “T”, the turn-on loss can be minimized. However, the characteristics of the TG-IGBT 10 are changed due to environmental fluctuation and aging degradation of the element or the like. The environmental fluctuation is, for example, change in the characteristics of the TG-IGBT 10, a peripheral circuit, and a load accompanying the change in an external temperature and heat generation of the element. In addition, a difference in the characteristics may be large for each component of the TG-IGBT 10. When the characteristics of the TG-IGBT 10 are changed, “ton1” and “ton2” that minimize the turn-on loss are also changed.

In the present embodiment 1, even when “ton1” and “ton2” that minimize the turn-on loss are changed due to the environmental fluctuation and the aging degradation of the element, feedback control of adaptively adjusting “ton1” and “ton2” is performed accompanying that. The feedback control here refers to processing of adjusting next “ton1” and “ton2” so as to minimize the turn-on loss based on the transition time “T” acquired using the present “ton1” and “ton2”. Specifically, the transition time “T” is considered as a function of “ton1” and “ton2”, and “ton1” and “ton2” that minimize the transition time “T” are searched using a gradient descent method.

Here, the feedback control according to the present embodiment 1 will be described in detail. Here, as an example, a use case that the drive system 100 of the TG-IGBT 10 is incorporated in a power converter as a final product is assumed. The TG-IGBT 10 incorporated in the power converter repeats the switching operation according to each pulse signal applied from the control circuit 20.

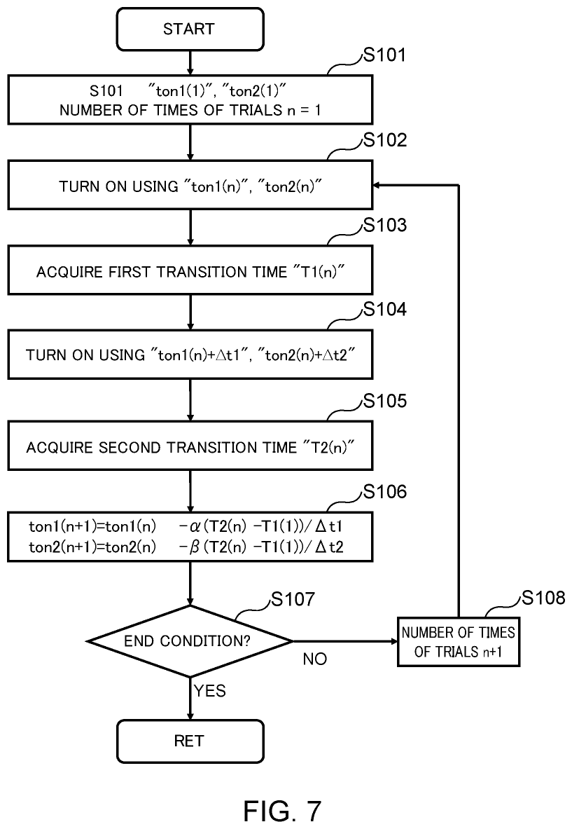

The control circuit 20 monitors the transition time “T” correlated with the turn-on loss of the TG-IGBT 10 at all times, and starts the feedback control illustrated in a flowchart in FIG. 7 if the transition time “T” exceeds a predetermined reference value and deterioration of the turn-on loss is detected.

In step S101, the control circuit 20 sets “ton1” and “ton2” at initial values “ton1(1)” and “ton2(1)”, respectively. In addition, the number (n) of times of trials is set at an initial value 1. When the feedback control is executed for the first time, for example, “ton1” and “ton2” are changed at a prescribed step interval in advance, the ones that minimize the turn-on loss are selected from them, and they are defined as the initial values “ton1(1)” and “ton2(1)”. When the feedback control is executed for the second time and thereafter, the present “ton1” and “ton2” are defined as the initial values “ton1(1)” and “ton2(1)” as they are.

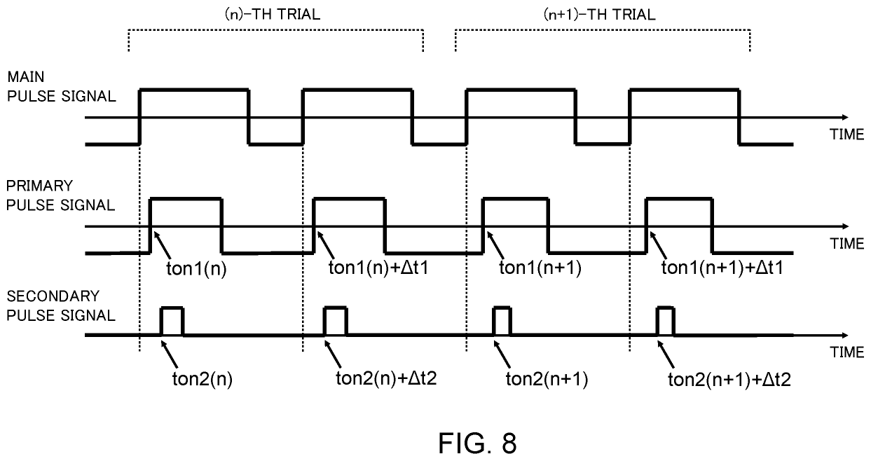

In step S102, the control circuit 20 turns on the TG-IGBT 10 using “ton1(n)” and “ton2(n)” at the time of an (n)-th trial by taking advantage of the switching operation of the TG-IGBT 10 that is continued even while the feedback control is executed (see FIG. 8). More specifically, the control circuit 20 starts the main pulse signal first, starts the primary pulse signal “ton1(n)” after the rise timing of the main pulse signal, and starts the secondary pulse signal “ton2(n)” after the rise timing of the main pulse signal.

In step S103, the control circuit 20 acquires first transition time “T1(n)” at the time of the (n)-th trial. More specifically, the control circuit 20 acquires the first transition time “T1(n)” as the time from when the first comparison signal S1 of the comparator circuit 40 changes from “Low” to “High” to when the second comparison signal S2 of the comparator circuit 40 changes from “Low” to “High”, when the TG-IGBT 10 is turned on. Thereafter, as the switching operation of the TG-IGBT 10 continued even while the feedback control is executed, the primary pulse signal and the secondary pulse signal fall at the timings “toff1” and “toff2” determined in advance.

In step S104, the control circuit 20 turns on the TG-IGBT 10 using “ton1(n)+Δt1” and “ton2(n)+At2” obtained by changing “ton1(n)” and “ton2(n)” at the time of the (n)-th trial only for a minute amount (predetermined amount) by taking advantage again of the switching operation of the TG-IGBT 10 that is continued even while the feedback control is executed (see FIG. 8). More specifically, the control circuit 20 starts the main pulse signal first, starts the primary pulse signal “ton1(n)+Δt1” after the rise timing of the main pulse signal, and starts the secondary pulse signal “ton2(n)+Δt2” after the rise timing of the main pulse signal. Note that minute amounts “Δt1” and “Δt2” may be the same values or may be different values. The minute amounts “Δt1” and “Δt2” are set to, for example, the time according to an operation speed of a circuit (FPGA, for example), the time per sample of the operation speed for example. When the operation speed is 100 MHz, “Δt1” and “Δt2” are set at 10 nanoseconds. However, a method of setting “Δt1” and “Δt2” is not limited to this method, and “Δt1” and “Δt2” may be set to the time of two samples or more, or may be set from a viewpoint different from the operation speed.

In step S105, the control circuit 20 acquires second transition time “T2(n)” at the time of the (n)-th trial. More specifically, the control circuit 20 acquires the second transition time “T2(n)” as the time from when the first comparison signal S1 of the comparator circuit 40 changes from “Low” to “High” to when the second comparison signal S2 of the comparator circuit 40 changes from “Low” to “High”, when the TG-IGBT 10 is turned on. Thereafter, as the switching operation of the TG-IGBT 10 continued even while the feedback control is executed, the primary pulse signal and the secondary pulse signal fall at the timings “toff1” and “toff2” determined in advance.

In step S106, the control circuit 20 updates “ton1(n)” and “ton2(n)” based on the first transition time “T1(n)” and the second transition time “T2(n)” at the time of the (n)-th trial. More specifically, the control circuit 20 calculates “ton1(n+1)” and “ton2(n+1)” according to expressions below from the first transition time “T1(n)” and the second transition time “T2(n)”.

$$ton 1 ( n + 1 ) = ton 1 ( n ) - α ( T 2 ( n ) - T 1 ( n ) ) / Δ t 1$$

$$ton 2 ( n + 1 ) = ton 2 ( n ) - β ( T 2 ( n ) - T 1 ( n ) ) / Δ t 2$$

In the expressions above, “α” and “β” are learning rates and may be the same values or may be different values. In addition, the learning rates “α” and “β” may be changed for each trial.

In step S107, the control circuit 20 determines an end condition of a search. For example, the control circuit 20 determines whether or not two conditional expressions below are both satisfied.

$$\vert ton 1 ( n + 1 ) - ton 1 ( n ) \vert < ε 1$$

$$\vert ton 2 ( n + 1 ) - ton 2 ( n ) \vert < ε2$$

In the expressions above, “ε1” and “ε2” are values (predetermined values) for convergence determination and may be the same values or may be different values.

If the end condition is established in step S107 (S107=YES), the control circuit 20 ends the search (RET). Otherwise (S107=NO), the control circuit 20 adds 1 to the number “n” of times of trials (S108), and returns to step S102.

“ton1(n)” and “ton2(n)” when the search is ended are adjusted so as to reduce, minimize for example, the turn-on loss in the present characteristics of the TG-IGBT 10. The control circuit 20 can reduce, minimize for example, the turn-on loss by controlling the switching operation of the TG-IGBT 10 using “ton1” and “ton2” adjusted in this way.

As described above, by executing the feedback control in FIG. 7 when the turn-on loss of the TG-IGBT 10 is deteriorated, even when “ton1” and “ton2” that minimize the turn-on loss are changed due to the environmental fluctuation and the aging degradation, “ton1” and “ton2” can be adaptively adjusted accompanying that. Further, the feedback control may be executed not only when the turn-on loss is deteriorated but also at a fixed time interval. However, because of the nature of the gradient descent method, it is possible that “ton1” and “ton2” at the end of the search correspond not to global minima of the turn-on loss but to local minima. Even in this case, the turn-on loss can be reduced.

As described above, in the drive system 100 of the multi-gate element according to the present embodiment 1, the control circuit 20 acquires the transition time “T” corresponding to a duration from when the voltage “Vn” associated with the collector-emitter voltage “Vce” (i.e., a voltage associated with an inter-electrode voltage between a first electrode and a second electrode of the multi-gate element) falls below the first voltage “Vth1” to when it falls below the second voltage “Vth2” during turn-on of the TG-IGBT 10 based on the comparison result of the comparator circuit 40. The control circuit 20 adjusts the rise timing “ton1” of the primary pulse signal and the rise timing “ton2” of the secondary pulse signal so as to reduce, preferably minimize, the transition time “T”. By such a feature, the drive system 100 according to the present embodiment 1 can reduce, preferably minimize, the turn-on loss even when the characteristics of the TG-IGBT 10 are changed due to the environmental fluctuation and the aging degradation of the element.

In addition, in the present embodiment 1, the turn-on loss is not estimated from a product of the collector-emitter voltage and a collector current of the TG-IGBT 10, but the turn-on loss is reduced based on the transition time “T” by utilizing the correlation between the turn-on loss and the transition time “T”. Normally, in order to measure the collector current of the TG-IGBT, a current sense resistor and a wideband current sensor or the like are required. The current sense resistor involves loss occurrence and the wideband current sensor is expensive. In contrast, in the present embodiment 1, the voltage divider circuit 30 and the comparator circuit 40 for acquiring the transition time “T” acquire the transition time “T” based on the voltage “Vn” obtained by dividing the collector-emitter voltage “Vce”, and are formed of only a small number of resistors and comparators. Therefore, the voltage divider circuit 30 and the comparator circuit 40 in the present embodiment 1 are of low loss, a small size, and a low cost. Such features are particularly advantageous when the drive system 100 is incorporated in a final product loaded with the TG-IGBT 10.

Further, when the feedback control according to the present embodiment 1 is executed for the first time, in step S101 in FIG. 7, “ton1” and “ton2” are changed at a prescribed step interval in advance, the ones that minimize the turn-on loss are selected from them, and they are defined as the initial values “ton1(1)” and “ton2(1)”. Thus, the search of the gradient descent method can be started from near the global minima. As a result, it is highly possible that “ton1” and “ton2” at the end of the search correspond to the global minima of the turn-on loss.

Note that, when an object is to reduce the turn-on loss, under an ideal condition without dispersion of the characteristics of the element and the circuit, it is preferable that the voltage of the secondary pulse signal starts to rise from the time when the voltage of the main pulse signal reaches 0 V. Actually, with reference to FIG. 4 and FIG. 5, while “ton1” that minimizes the turn-on loss is almost zero, “ton2” that minimizes the turn-on loss, that is “ton2_*”, is a value larger than zero.

Therefore, when selecting “ton1” and “ton2” that minimize the turn-on loss, it is preferable to select “ton2” first and then select “ton1”. Specifically, “ton1” is fixed at zero first, “ton2” is changed at a predetermined step interval, and the one that minimizes the turn-on loss is selected from them and is defined as the initial value “ton2(1)”. Next, “ton2” is fixed at the initial value “ton2(1)”, “ton1” is changed at the predetermined step interval, and the one that minimizes the turn-on loss is selected from them and is defined as the initial value “ton1(1)”.

Further, while “ton1” and “ton2” are simultaneously adjusted in the feedback control of the present embodiment 1, “ton1” and “ton2” may be independently adjusted. For example, “ton2” that has larger effect on the turn-on loss may be adjusted first and then “ton1” may be adjusted. In this case, “ton1” may be fixed at zero while “ton2” is adjusted. Alternatively, “ton1” with smaller effect on the turn-on loss may be fixed at zero and only “ton2” with the larger effect on the turn-on loss may be adjusted.

### Embodiment 2

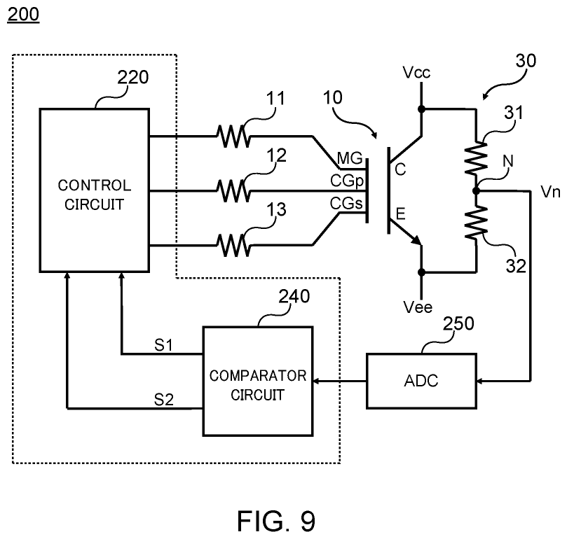

FIG. 9 is a diagram illustrating a configuration of a drive system 200 of the multi-gate element according to Embodiment 2. The drive system 200 includes an A/D converter 250 configured to convert the voltage “Vn” divided by the voltage divider circuit 30 to a digital signal. A comparator circuit 240 compares sizes of the voltage “Vn” converted to the digital signal by the A/D converter 250 and a quantized first voltage “Vth1” (the first voltage “Vth1” of the digital signal) or a quantized second voltage “Vth2” (the second voltage “Vth2” of the digital signal) respectively, and outputs a comparison result as the digital signal.

In Embodiment 1 described above, the comparator circuit 40 is configured as an analog circuit. In contrast, in the present embodiment 2, the comparator circuit 240 is configured as a digital circuit. As a result, signals in an area surrounded by dotted lines in the figure are all digital signals. Thus, for example, a control circuit 220 and the comparator circuit 240 can be formed of the same FPGA, CPU, or ASIC or the like.

### Embodiment 3

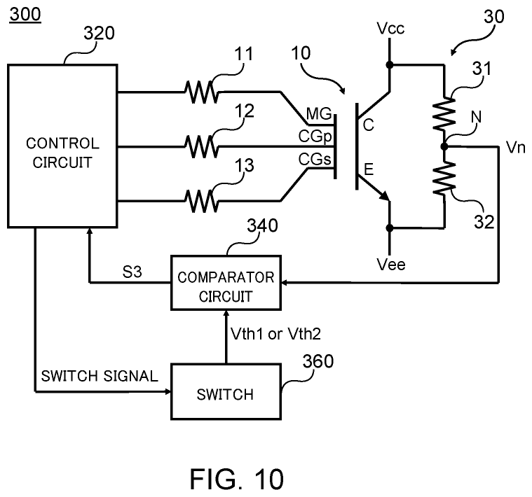

FIG. 10 is a diagram illustrating a configuration of a drive system 300 of the multi-gate element according to Embodiment 3. The drive system 300 includes a switch 360 configured to selectively output either one of the first voltage “Vth1” and the second voltage “Vth2” according to a switch signal input from a control circuit 320. The switch 360 may selectively generate and output the first voltage “Vth1” or the second voltage “Vth2” within itself, or may selectively output the first voltage “Vth1” or the second voltage “Vth2” input from an outside.

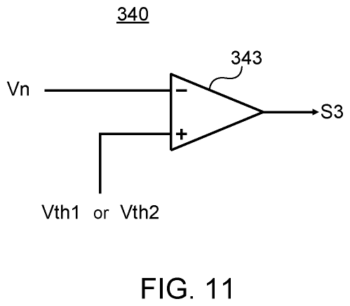

A comparator circuit 340 compares the voltage “Vn” divided by the voltage divider circuit 30 with either one of the first voltage “Vth1” and the second voltage “Vth2” output from the switch 360, and outputs a comparison result. FIG. 11 is a diagram illustrating a detailed configuration of the comparator circuit 340. The comparator circuit 340 includes a third comparator 343, the voltage “Vn” is input to negative input of the third comparator 343, and either one of the first voltage “Vth1” and the second voltage “Vth2” is input to positive input. Output of the third comparator 343 is a third comparison signal S3, and is input to the control circuit 320.

When acquiring the transition time “T”, the control circuit 320 makes the first voltage “Vth1” be output from the switch 360 first, and acquires first elapsed time “Tp1” from a predetermined reference time to when output of the comparator circuit 340 changes. The reference time is set at the rise timing of the main pulse signal, for example. Next, the control circuit 320 makes the second voltage “Vth2” be output from the switch 360, and acquires second elapsed time “Tp2” from the reference time described above to when the output of the comparator circuit 340 changes. The comparator circuit 340 calculates the transition time “T” from a difference between the second elapsed time “Tp2” and the first elapsed time “Tp1”.

In Embodiment 1 described above, the comparator circuit 40 is formed of the two comparators 41 and 42 and the three resistors 43 to 45. In contrast, in the present embodiment 3, the comparator circuit 340 is formed of only one comparator 343. By such a feature, the comparator circuit 340 of the present embodiment 3 has a smaller number of components and is of a smaller size and a lower cost, compared to the comparator circuit 40 of Embodiment 1.

In addition, in the present embodiment 3, when the reference time is set at the rise timing of a main gate signal, “Tp1”<<“Tp2” is satisfied. Further, “ton2” has the larger effect on the turn-on loss than “ton1”. Therefore, when adjusting “ton1” with the smaller effect on the turn-on loss, it is possible to approximate to the transition time “T”≈the second elapsed time “Tp2”.

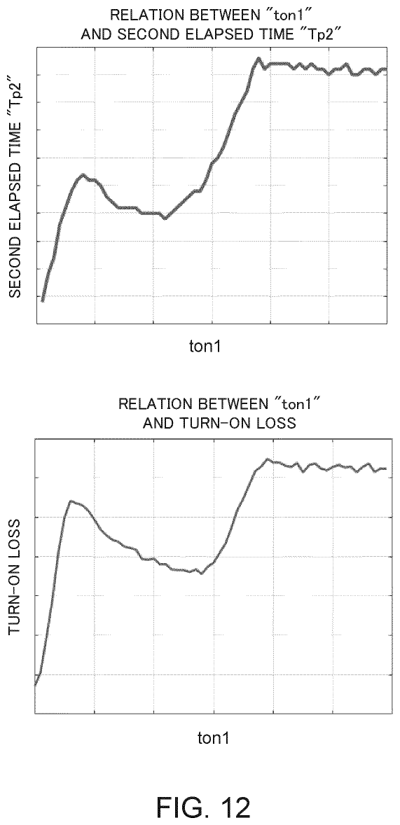

Actually, as illustrated in FIG. 12, a relation between “ton1” and the second elapsed time “Tp2” when “ton1” is manually changed (a graph on an upper side of FIG. 12) and a relation between “ton1” and the turn-on loss when “ton1” is manually changed (a graph on a lower side of FIG. 12) are extremely similar.

Therefore, when adjusting “ton1” by the feedback control, the control circuit 320 may approximate the transition time “T” by the second elapsed time “Tp2” and adjust “ton1” so that the second elapsed time “Tp2” is reduced. Thus, since a process of acquiring “Tp1” is not needed when adjusting “ton1”, time required for adjusting “ton1” is shortened, and the feedback control can be accelerated. However, when adjusting “ton2” with the large effect on the turn-on loss, contribution of the first elapsed time “Tp1” cannot be ignored, and adjustment needs to be made based on the transition time “T”=“Tp2”−“Tp1”.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The embodiments of the present invention can also be configured as follows.

### (Clauses)

Clause 1 (Embodiments 1 to 3). An electronic circuitry comprising:
   a control circuit configured to control a rise timing of a first pulse signal applied to a first control gate electrode of a multi-gate element; and
   a comparator circuit configured to acquire a comparison result between
      a voltage associated with an inter-electrode voltage between a first electrode and a second electrode of the multi-gate element and
      a first voltage or a second voltage smaller than the first voltage,
   wherein the control circuit is configured to, based on the comparison result,
      acquire transition time corresponding to a duration from when the voltage associated with the inter-electrode voltage falls below the first voltage to when the voltage associated with the inter-electrode voltage falls below the second voltage during turn-on of the multi-gate element, and
      adjust the rise timing of the first pulse signal so as to reduce the transition time.
Clause 2 (Embodiments 1 to 3). The electronic circuitry according to claim 1,
   wherein the control circuit is configured to further control a rise timing of a second pulse signal applied to a second control gate electrode of the multi-gate element, and adjust the rise timing of the second pulse signal so as to reduce the transition time.
Clause 3 (Embodiments 1 to 3). The electronic circuitry according to claim 1 or 2,
   wherein the control circuit is configured to adjust the rise timings of the first pulse signal and the second pulse signal so as to minimize the transition time.
Clause 4 (Embodiments 1 to 3). The electronic circuitry according to claim 2 or 3,
   wherein the rise timings of the first pulse signal and the second pulse signal represent relative delay times with respect to a rise timing of a main pulse signal applied to a main gate electrode of the multi-gate element.
Clause 5 (Embodiments 1 to 3). The electronic circuitry according to claim 1, further comprising
   a voltage divider circuit configured to divide the voltage between the first electrode and the second electrode,
   wherein the voltage divided by the voltage divider circuit is input to the comparator circuit.
Clause 6 (Embodiments 1 to 3). The electronic circuitry according to claim 5,
   wherein the voltage divider circuit includes two resistors, and at least one of the two resistors is a variable resistor.
Clause 7 (Embodiment 1). The electronic circuitry according to claim 5 or 6,
   wherein the comparator circuit includes
   a first comparator configured to compare the divided voltage and the first voltage and to output a comparison result, and
   a second comparator configured to compare the divided voltage and the second voltage and to output a comparison result, and
   the control circuit acquires the transition time based on output of the first comparator and the second comparator.
Clause 8 (Embodiment 1). The electronic circuitry according to claim 7,
   wherein the control circuit is configured to acquire the transition time based on the time from when the output of the first comparator changes to when the output of the second comparator changes.
Clause 9 (Embodiment 2). The electronic circuitry according to claim 5, further comprising
   an A/D converter configured to convert the divided voltage to a digital signal,
   wherein the comparator circuit is configured to compare the digital signal of the divided voltage and the first voltage represented in digital form or the second voltage represented in digital form and acquire the comparison result as the digital signal.
Clause 10 (Embodiments 1 to 3). The electronic circuitry according to any one of claims 2 to 9,
   wherein the rise timings of the first pulse signal and the second pulse signal are adjusted in a direction which reduces the transition time, in response to a predetermined amount of change in the rise timings of the first pulse signal and the second pulse signal.
Clause 11 (Embodiments 1 to 3). The electronic circuitry according to claim 10,
   wherein adjustment of the rise timings of the first pulse signal and the second pulse signal ends when an amount of change in the transition time resulting from the predetermined amount of change in the rise timings of the first pulse signal and the second pulse signal becomes equal to or less than a predetermined value.
Clause 12 (Embodiments 1 to 3). The electronic circuitry according to any one of claims 2 to 11,
   wherein the rise timings of the first pulse signal and the second pulse signal are independently adjusted, respectively.
Clause 13 (Embodiments 1 to 3). The electronic circuitry according to any one of claims 2 to 12,
   wherein initial values of the rise timings of the first pulse signal and the second pulse signal are set at timings that minimize the transition time when the rise timings of the first pulse signal and the second pulse signal are changed at predetermined step intervals.
Clause 14 (Embodiments 1 to 3). The electronic circuitry according to claim 13,
   wherein the initial value of the rise timing of the second pulse signal is set and then the initial value of the rise timing of the first pulse signal is set.
Clause 15 (Embodiment 3). The electronic circuitry according to claim 5,
   wherein the comparator circuit includes
   a switch configured to selectively output either one of the first voltage and the second voltage according to a switch signal input from the control circuit, and
   a third comparator configured to compare the divided voltage and either one of the first voltage and the second voltage output from the switch and to output a comparison result, and
   the control circuit is configured to output the first voltage via the switch, acquires first elapsed time from a predetermined reference time to a time when output of the third comparator changes, then output the second voltage via the switch, acquire second elapsed time from the reference time to a time when the output of the third comparator changes, and acquire the transition time based on a difference between the first elapsed time and the second elapsed time.
Clause 16 (Embodiment 3). The electronic circuitry according to claim 15,
   wherein the reference time is a rise timing of a main pulse signal applied to a main gate electrode of the multi-gate element.
Clause 17 (Embodiment 3). The electronic circuitry according to claim 15 or 16,
   wherein the control circuit is configured to further control a rise timing of a second pulse signal applied to a second control gate electrode of the multi-gate element, and adjust the rise timing of the second pulse signal so as to reduce the second elapsed time.
Clause 18 (Embodiments 1 to 3). A method of driving a multi-gate element, comprising:
   acquiring a comparison result between
      a voltage associated with an inter-electrode voltage between a first electrode and a second electrode of the multi-gate element and
      a first voltage or a second voltage smaller than the first voltage;
   acquiring transition time corresponding to a duration from when the voltage associated with the inter-electrode voltage falls below the first voltage to when the voltage associated with the inter-electrode voltage falls below the second voltage during turn-on of the multi-gate element; and
   adjusting a rise timing of a first pulse signal applied to a first control gate electrode of the multi-gate element so as to reduce the transition time.
Clause 19 (Embodiments 1 to 3). An electronic system comprising:
   a multi-gate element;
   a control circuit configured to control a rise timing of a first pulse signal applied to a first control gate electrode of the multi-gate element; and
   a comparator circuit configured to acquire a comparison result between
      a voltage associated with an inter-electrode voltage between a first electrode and a second electrode of the multi-gate element and
      a first voltage or a second voltage smaller than the first voltage,
   wherein the control circuit is configured to, based on the comparison result,
      acquire transition time corresponding to a duration from when the voltage associated with the inter-electrode voltage falls below the first voltage to when the voltage associated with the inter-electrode voltage falls below the second voltage during turn-on of the multi-gate element, and
      adjust the rise timing of the first pulse signal so as to reduce the transition time.

1. An electronic circuitry comprising:
a control circuit configured to control a rise timing of a first pulse signal applied to a first control gate electrode of a multi-gate element; and
a comparator circuit configured to acquire a comparison result between
a voltage associated with an inter-electrode voltage between a first electrode and a second electrode of the multi-gate element and
a first voltage or a second voltage smaller than the first voltage,
wherein the control circuit is configured to, based on the comparison result,
acquire transition time corresponding to a duration from when the voltage associated with the inter-electrode voltage falls below the first voltage to when the voltage associated with the inter-electrode voltage falls below the second voltage during turn-on of the multi-gate element, and
adjust the rise timing of the first pulse signal so as to reduce the transition time.

2. The electronic circuitry according to claim 1,
wherein the control circuit is configured to further control a rise timing of a second pulse signal applied to a second control gate electrode of the multi-gate element, and adjust the rise timing of the second pulse signal so as to reduce the transition time.

3. The electronic circuitry according to claim 2,
wherein the control circuit is configured to adjust the rise timings of the first pulse signal and the second pulse signal so as to minimize the transition time.

4. The electronic circuitry according to claim 2,
wherein the rise timings of the first pulse signal and the second pulse signal represent relative delay times with respect to a rise timing of a main pulse signal applied to a main gate electrode of the multi-gate element.

5. The electronic circuitry according to claim 1, further comprising
a voltage divider circuit configured to divide the voltage between the first electrode and the second electrode,
wherein the voltage divided by the voltage divider circuit is input to the comparator circuit.

6. The electronic circuitry according to claim 5,
wherein the voltage divider circuit includes two resistors, and at least one of the two resistors is a variable resistor.

7. The electronic circuitry according to claim 5,
wherein the comparator circuit includes
a first comparator configured to compare the divided voltage and the first voltage and to output a comparison result, and
a second comparator configured to compare the divided voltage and the second voltage and to output a comparison result, and
the control circuit acquires the transition time based on output of the first comparator and the second comparator.

8. The electronic circuitry according to claim 7,
wherein the control circuit is configured to acquire the transition time based on the time from when the output of the first comparator changes to when the output of the second comparator changes.

9. The electronic circuitry according to claim 5, further comprising
an A/D converter configured to convert the divided voltage to a digital signal,
wherein the comparator circuit is configured to compare the digital signal of the divided voltage and the first voltage represented in digital form or the second voltage represented in digital form and acquire the comparison result as the digital signal.

10. The electronic circuitry according to claim 2,
wherein the rise timings of the first pulse signal and the second pulse signal are adjusted in a direction which reduces the transition time, in response to a predetermined amount of change in the rise timings of the first pulse signal and the second pulse signal.

11. The electronic circuitry according to claim 10,
wherein adjustment of the rise timings of the first pulse signal and the second pulse signal ends when an amount of change in the transition time resulting from the predetermined amount of change in the rise timings of the first pulse signal and the second pulse signal becomes equal to or less than a predetermined value.

12. The electronic circuitry according to claim 2,
wherein the rise timings of the first pulse signal and the second pulse signal are independently adjusted, respectively.

13. The electronic circuitry according to claim 2,
wherein initial values of the rise timings of the first pulse signal and the second pulse signal are set at timings that minimize the transition time when the rise timings of the first pulse signal and the second pulse signal are changed at predetermined step intervals.

14. The electronic circuitry according to claim 13,
wherein the initial value of the rise timing of the second pulse signal is set and then the initial value of the rise timing of the first pulse signal is set.

15. The electronic circuitry according to claim 5,
wherein the comparator circuit includes
a switch configured to selectively output either one of the first voltage and the second voltage according to a switch signal input from the control circuit, and
a third comparator configured to compare the divided voltage and either one of the first voltage and the second voltage output from the switch and to output a comparison result, and
the control circuit is configured to output the first voltage via the switch, acquires first elapsed time from a predetermined reference time to a time when output of the third comparator changes, then output the second voltage via the switch, acquire second elapsed time from the reference time to a time when the output of the third comparator changes, and acquire the transition time based on a difference between the first elapsed time and the second elapsed time.

16. The electronic circuitry according to claim 15,
wherein the reference time is a rise timing of a main pulse signal applied to a main gate electrode of the multi-gate element.

17. The electronic circuitry according to claim 15,
wherein the control circuit is configured to further control a rise timing of a second pulse signal applied to a second control gate electrode of the multi-gate element, and adjust the rise timing of the second pulse signal so as to reduce the second elapsed time.

18. A method of driving a multi-gate element, comprising:
acquiring a comparison result between
a voltage associated with an inter-electrode voltage between a first electrode and a second electrode of the multi-gate element and
a first voltage or a second voltage smaller than the first voltage;
acquiring transition time corresponding to a duration from when the voltage associated with the inter-electrode voltage falls below the first voltage to when the voltage associated with the inter-electrode voltage falls below the second voltage during turn-on of the multi-gate element; and
adjusting a rise timing of a first pulse signal applied to a first control gate electrode of the multi-gate element so as to reduce the transition time.

19. An electronic system comprising:
a multi-gate element;
a control circuit configured to control a rise timing of a first pulse signal applied to a first control gate electrode of the multi-gate element; and
a comparator circuit configured to acquire a comparison result between
a voltage associated with an inter-electrode voltage between a first electrode and a second electrode of the multi-gate element and
a first voltage or a second voltage smaller than the first voltage,
wherein the control circuit is configured to, based on the comparison result,
acquire transition time corresponding to a duration from when the voltage associated with the inter-electrode voltage falls below the first voltage to when the voltage associated with the inter-electrode voltage falls below the second voltage during turn-on of the multi-gate element, and
adjust the rise timing of the first pulse signal so as to reduce the transition time.
